(19) United States
(12) Patent Application Publication
(10) Pub. No.: US 2018/0278791 A1
(43) Pub. Date: Sep. 27, 2018

(54) IMAGE READING DEVICE AND SEMICONDUCTOR DEVICE

(71) Applicant: SEIKO EPSON CORPORATION, Tokyo (JP)

(72) Inventor: Takafumi SANO, Matsumoto-shi (JP)

(73) Assignee: SEIKO EPSON CORPORATION, Tokyo (JP)

(21) Appl. No.: 15/918,249

(22) Filed: Mar. 12, 2018

(30) Foreign Application Priority Data
Mar. 22, 2017 (JP) 2017-056346

(51) Int. Cl. H04N 1/193; H04N 5/378

(52) U.S. Cl. CPC H04N 1/1937; H04N 5/378

(57) ABSTRACT

An image reading chip includes: a first pixel that includes a first photodetector that receives light of a reduced image of a portion of an image and performs photoelectric conversion, and generates a first pixel signal by amplifying a signal generated by the photoelectric conversion; a second pixel that includes a second photodetector that receives light of a reduced image of a portion of the image and performs photoelectric conversion, and generates a second pixel signal by amplifying a signal generated by the photoelectric conversion; and a pseudo pixel that is not involved in reading the image. The first pixel, the second pixel, and the pseudo pixel are arranged along a first side, and the distance between the pseudo pixel and the second side is shorter than the distance between the first pixel and the second side and the distance between the second pixel and the second side.

### BACKGROUND

### 1. Technical Field

The present invention relates to image reading devices and semiconductor devices.

### 2. Related Art

Image reading devices (such as scanners) that use line sensors, and copy machines and multifunctional printers that have a print function in addition to a scan function have been developed. A line sensor used in image reading devices is configured to include photodiodes provided on a semiconductor substrate.

A line sensor used in image reading devices such as a scanner is configured by connecting a plurality of semiconductor chips in each of which a plurality of pixels each including one or a plurality of photodiodes are unidirectionally arranged side by side. However, in the case where a plurality of semiconductor chips are connected, it is possible that a pixel will be defective or image distortion will occur at connection portions.

In JP-A-2015-222895, an interpolation method with respect to pixels corresponding to the connection portions of pixels provided in the semiconductor chips, in a contact image sensor in which a plurality of semiconductor chips are used, is disclosed.

The factors leading to a defective pixel or image distortion in a semiconductor chip includes a factor that is caused by variations in characteristics of pixels or the like due to variations in manufacturing of the semiconductor chip. It is possible that variations in manufacturing of the semiconductor chip are larger in pixels arranged at an end portion relative to pixels arranged at a central portion, the pixels being arranged side by side in the semiconductor chip.

Meanwhile, there are cases in which a degree of freedom in the layout of circuits, interconnects, and the like in a semiconductor chip that constitutes the line sensor is limited by the configuration of an optical system used in an image reading device such as a scanner. Accordingly, there is a problem in that it is difficult to take a measure for reducing variations in manufacturing the semiconductor chip.

### SUMMARY

According to some aspects of the invention, an image reading device can be provided that can, in a line sensor including an optical system that forms a reduced image on a semiconductor chip, accurately read an image as a result of reducing variations in manufacturing a semiconductor chip. Also, according to some aspects of the invention, a semiconductor device that can accurately read an image can be provided.

These and other advantages can be realized as the following modes or application examples.

### Application Example 1

An image reading device according to the present application example includes: a first image reading chip that reads an image; and an optical unit that forms a reduced image of the image on the first image reading chip. The first image reading chip includes: a first pixel that includes a first photodetector that receives light of a reduced image of the image and performs photoelectric conversion, and generates a first pixel signal by amplifying a signal generated by the photoelectric conversion; a second pixel that includes a second photodetector that receives light of a reduced image of the image and performs photoelectric conversion, and generates a second pixel signal by amplifying a signal generated by the photoelectric conversion; a first readout circuit that is electrically connected to the first pixel and outputs a first readout signal based on the first pixel signal; a second readout circuit that is electrically connected to the second pixel and outputs a second readout signal based on the second pixel signal; and a pseudo pixel that is not involved in reading of the image. The first image reading chip has a shape that includes a first side and a second side that is shorter than the first side. The first pixel, the second pixel, and the pseudo pixel are arranged side by side in a direction in which the first side extends. A distance between the pseudo pixel and the second side is shorter than a distance between the first pixel and the second side, and the distance between the pseudo pixel and the second side is shorter than a distance between the second pixel and the second side.

In the image reading device according to the present application example, light of a portion of a reduced image is incident on the first pixel or the second pixel. That is, a reduced image is formed on the image reading chip. Therefore, the first pixel and the second pixel need not be arranged up to an end portion of the image reading chip. Therefore, the degree of freedom in the internal layout of the image reading chip increases.

Also, the image reading device according to the present application example includes the first pixel and the second pixel that are involved in reading of an image, and the pseudo pixel that is not involved in reading of an image. The first pixel, the second pixel, and the pseudo pixel are provided side by side along a direction in which the first side extends. Here, the pseudo pixel is provided closer to the second side relative to the first pixel and the second pixel. That is, the pseudo pixel is provided at an end portion on the second side relative to the first pixel and the second pixel that are provided side by side. As a result of arranging the pseudo pixel that is not involved in reading of an image at the end portion at which variations in characteristics are large, variations in the first pixel and the second pixel that are involved in reading of an image can be reduced. Accordingly, an image can be accurately read with the first pixel and the second pixel, and the image reading accuracy of the image reading device is improved.

### Application Example 2

In the image reading device according to the above-described application example, the first pixel, the second pixel, and the pseudo pixel may be arranged in a region that is surrounded by the same well.

In the image reading device according to the present application example, the region in which the first pixel, the second pixel, and the pseudo pixel are formed is surrounded by a well. That is, the region in which the first pixel, the second pixel, and the pseudo pixel are formed and a surrounding region are isolated by the well. As a result of isolating, in the image reading chip, the region in which the first pixel, the second pixel, and the pseudo pixel are formed from other regions, electrons that are not related to reading an image flowing into the first pixel and the second pixel can be reduced. Accordingly, an image can be accurately read with the first pixel and the second pixel, and the image reading accuracy of the image reading device improves.

### Application Example 3

In the image reading device according to the above-described application examples, the first image reading chip includes: a first amplification circuit that is included in the first readout circuit, and amplifies and outputs the first pixel signal; a second amplification circuit that is included in the second readout circuit, and amplifies and outputs the second pixel signal; and a pseudo amplification circuit that is not involved in reading the image. The first amplification circuit, the second amplification circuit, and the pseudo amplification circuit are arranged side by side in a direction in which the first side extends. A distance between the pseudo amplification circuit and the second side is shorter than a distance between the first amplification circuit and the second side, and the distance between the pseudo amplification circuit and the second side is shorter than a distance between the second amplification circuit and the second side.

In the image reading device according to the present application example, the first amplification circuit and the second amplification circuit that are involved in reading of an image and the pseudo amplification circuit that is not involved in reading of an image are provided side by side along a direction in which the first side extends. Here, the pseudo amplification circuit is provided closer to the second side relative to the first amplification circuit and the second amplification circuit. That is, the pseudo amplification circuit is provided at an end portion on the second side relative to the first amplification circuit and the second amplification circuit that are provided side by side. As a result of providing the pseudo amplification circuit that is not involved in reading of an image at an end portion at which variations in characteristics are large, variations in the first amplification circuit and the second amplification circuit that are involved in reading of an image can be reduced. Accordingly, the first amplification circuit and the second amplification circuit can accurately amplify the first pixel signal and the second pixel signal, respectively, and the image reading accuracy of the image reading device is improved.

### Application Example 4

In the image reading device according to the above-described application examples, the first image reading chip includes: a first scanning circuit that is included in the first readout circuit, and controls a readout timing of the amplified first pixel signal; a second scanning circuit that is included in the second readout circuit, and controls a readout timing of the amplified second pixel signal; and a pseudo scanning circuit that is not involved in reading of the image. The first scanning circuit, the second scanning circuit, and the pseudo scanning circuit are arranged side by side in a direction in which the first side extends. A distance between the pseudo scanning circuit and the second side is shorter than a distance between the first scanning circuit and the second side, and the distance between the pseudo scanning circuit and the second side is shorter than a distance between the second scanning circuit and the second side.

In the image reading device according to the present application example, the first scanning circuit and the second scanning circuit that are involved in reading of an image and the pseudo scanning circuit that is not involved in reading of an image are provided side by side along a direction in which the first side extends. Here, the pseudo scanning circuit is provided closer to the second side relative to the first scanning circuit and the second scanning circuit. That is, the pseudo scanning circuit is provided at an end portion on the second side relative to the first scanning circuit and the second scanning circuit that are provided side by side. As a result of providing the pseudo scanning circuit that is not involved in reading of an image at an end portion at which variations in characteristics are large, variations in the first scanning circuit and the second scanning circuit that are involved in reading of an image can be reduced. Accordingly, the first scanning circuit and the second scanning circuit can accurately read out the first pixel signal and the second pixel signal, respectively, and the image reading accuracy of the image reading device is improved.

### Application Example 5

The image reading device according to the above-described application example further includes a second image reading chip. The image includes a first partial image and a second partial image. The optical unit may form a reduced image of the first partial image on the first image reading chip, and form a reduced image of the second partial image on the second image reading chip.

The image reading device according to the present application example includes the first image reading chip and the second image reading chip, and the first image reading chip and the second image reading chip respectively read the first partial image and the second partial image, which are reduced images of portions of the image. That is, the first image reading chip and the second image reading chip each constitute an optical reduction system image reading device, and an image having a deep depth of field can be read. Furthermore, in the image reading device according to the present application example, the image reading device divides one image, and reads divided reduced images using the plurality of image reading chips, and as a result, the image reading device can be realized with a small reduction ratio relative to a known optical reduction system image reading device, and the optical path length for reducing the image can be reduced. Therefore, the depth of field can be increased, and the size of a liquid ejection device can be reduced.

### Application Example 6

A semiconductor device according to the present application example has a shape including a first side and a second side that is shorter than the first side. The semiconductor device includes: a first pixel that includes a first photodetector that receives light of a reduced image of a portion of an image and performs photoelectric conversion, and generates a first pixel signal by amplifying a signal generated by the photoelectric conversion; a second pixel that includes a second photodetector that receives light of a reduced image of a portion of the image and performs photoelectric conversion, and generates a second pixel signal by amplifying a signal generated by the photoelectric conversion; a first readout circuit that is electrically connected to the first pixel and outputs a first readout signal based on the first pixel signal; a second readout circuit that is electrically connected to the second pixel and outputs a second readout signal based on the second pixel signal; and a pseudo pixel that is not involved in reading the image. The first pixel, the second pixel, and the pseudo pixel are arranged side by side in a direction in which the first side extends. A distance between the pseudo pixel and the second side is shorter than a distance between the first pixel and the second side, and the distance between the pseudo pixel and the second side is shorter than a distance between the second pixel and the second side.

Also, the semiconductor device according to the present application example includes the first pixel and the second pixel that are involved in reading of an image, and the pseudo pixel that is not involved in reading of an image. The first pixel, the second pixel, and the pseudo pixel are provided side by side along a direction in which the first side extends. Here, the pseudo pixel is provided closer to the second side relative to the first pixel and the second pixel. That is, the pseudo pixel is provided at an end portion on the second side relative to the first pixel and the second pixel that are provided side by side. As a result of providing the pseudo pixel that is not involved in reading of an image at an end portion at which variations in characteristics are large, variations in first pixel and the second pixel that are involved in reading of an image can be reduced. Accordingly, an image can be accurately read with the first pixel and the second pixel, and the image reading accuracy of the image reading device improves.

### BRIEF DESCRIPTION OF THE DRAWINGS

The invention will be described with reference to the accompanying drawings, wherein like numbers reference like elements.

FIG. 1 is an external perspective view of a multifunction peripheral according to a present embodiment.

FIG. 2 is a perspective view of an internal structure of a scanner unit.

FIG. 3 is an exploded perspective view schematically illustrating a configuration of an image sensor module.

FIG. 4 is a plan view schematically illustrating an arrangement of image reading chips.

FIG. 5 is a schematic diagram illustrating a configuration of an optical portion of the image sensor module.

FIG. 6 is a schematic diagram for describing a divided optical reduction system

FIG. 7 is a block diagram illustrating a functional configuration of the scanner unit.

FIG. 8 is a block diagram illustrating a circuit configuration of the image reading chip.

FIG. 9 is a circuit configuration diagram illustrating a configuration of a pixel circuit and a column processing circuit.

FIG. 10 is a timing chart illustrating operation timings of a signal processing circuit.

FIG. 11 is a diagram illustrating an internal layout of the image reading chip.

FIG. 12 is a plan view illustrating a layout of the pixel circuits in the image reading chip.

FIG. 13 is a cross-sectional view illustrating a configuration of the pixel circuits in the image reading chip.

FIG. 14 is a plan view illustrating a layout of the column processing circuits and a dummy column processing circuit in the image reading chip.

FIG. 15 is a circuit configuration diagram illustrating a configuration of the dummy pixel circuit.

FIG. 16 is a circuit configuration diagram illustrating a configuration of the dummy column processing circuit.

### DESCRIPTION OF EXEMPLARY EMBODIMENTS

Hereinafter, preferred embodiments of the invention will be described in detail with reference to the drawings. The drawings used are provided to facilitate the understanding of the description. Note that the embodiments given below are not intended to unduly limit the scope of the invention recited in the appended claims. In addition, not all of the constituent elements described below are essential to the invention.

A description will be given below of a multifunction peripheral (multifunction peripheral apparatus) 1, to which an image reading device according to the invention is applied, with reference to the accompanying drawings.

1. Outline of Multifunction Peripheral

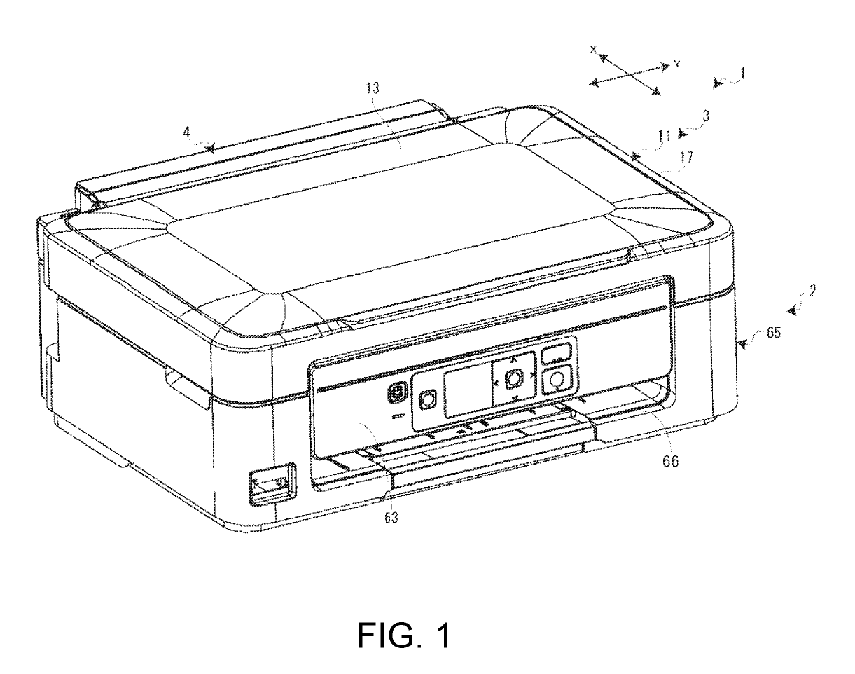

FIG. 1 is an external perspective view illustrating the multifunction peripheral 1. As shown in FIG. 1, the multifunction peripheral 1 integrally includes a printer unit (image recording device) 2 that is a device main body, and a scanner unit (image reading device) 3 that is an upper unit provided on top of the printer unit 2. Note that, in the following description, a front rear direction in FIG. 1 is defined as a main scanning direction X, and a right left direction is defined as a sub scanning direction Y. Also, the main scanning direction X and the sub scanning direction Y are described in the drawings as X and Y that are orthogonal to each other.

As shown in FIG. 1, the printer unit 2 includes: a conveyance portion (not shown) that conveys a sheet of recording medium (print paper or cut sheets) along a feed path; a printing portion (not shown) that is provided above the feed path, and performs inkjet print processing on the recording medium; a panel operation portion 63 provided on a front face; a device frame (not shown) incorporating the conveyance portion, the printing portion, and the operation portion 63; and a device housing 65 that covers the above-described constituent elements. The device housing 65 is provided with a discharge port 66 through which the printed recording medium is discharged. Although not shown in the diagram, a USB port and a power supply port are provided in a lower portion of a rear face. That is, the multifunction peripheral 1 is configured to be connectable to a computer and the like via the USB port.

The scanner unit 3 is pivotably supported by the printer unit 2 via a hinge 4 provided at a rear end, and covers a top portion of the printer unit 2 so as to be capable of opening and closing. That is, by raising the scanner unit 3 in the pivotal direction, an upper surface opening of the printer unit 2 is exposed so as to expose the inside of the printer unit 2 via the upper surface opening. On the other hand, by lowering the scanner unit 3 in the pivotal direction to place it on the printer unit 2, the upper surface opening is closed by the scanner unit 3. The configuration in which the scanner unit 3 can be opened in the manner as described above allows ink cartridge exchange, the clearance of paper jams, and the like to be performed.

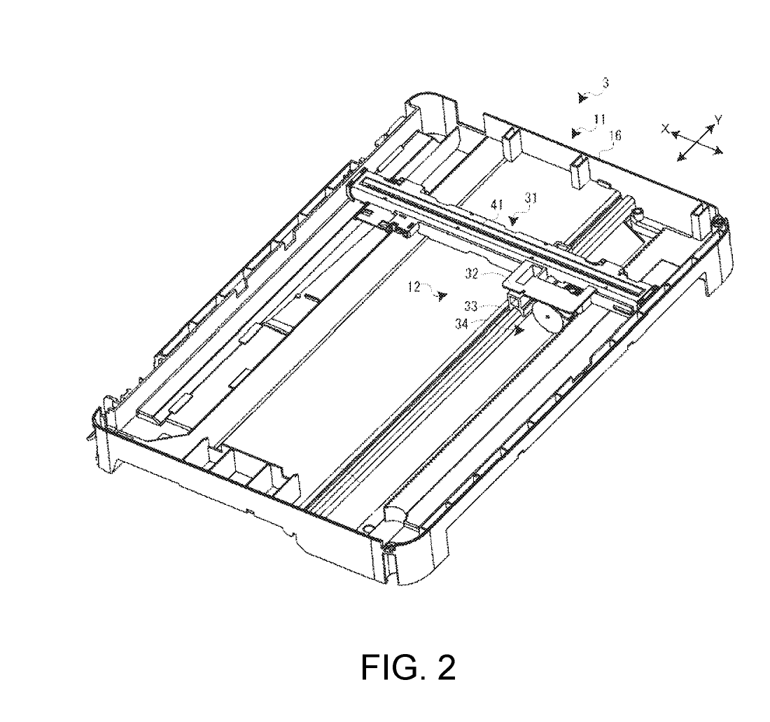

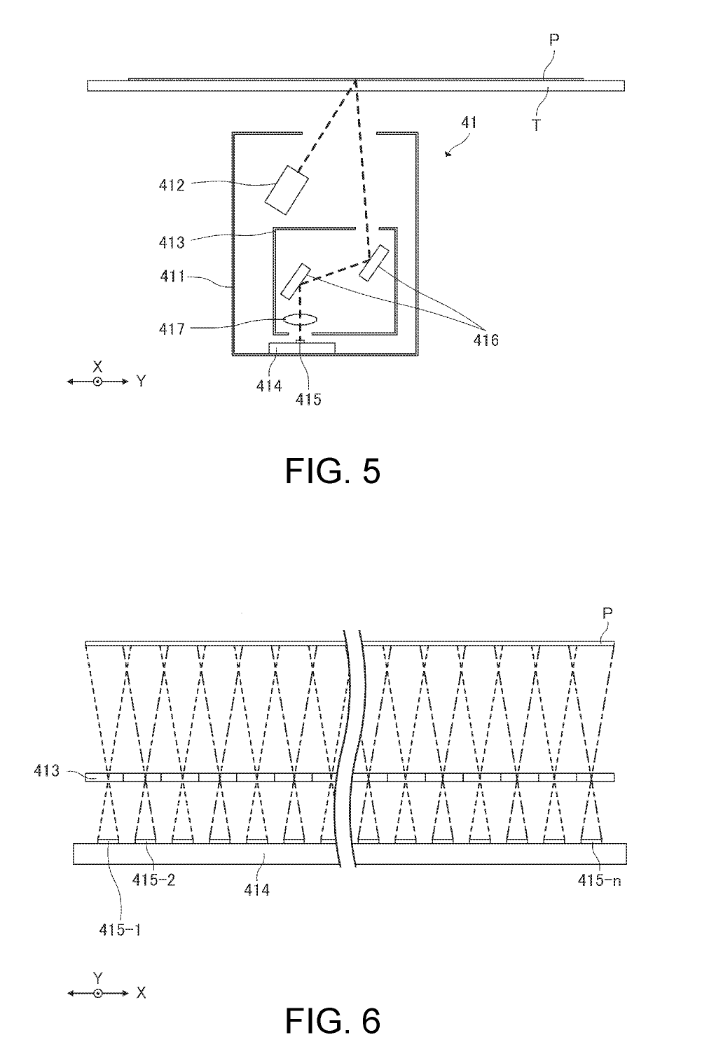

FIG. 2 is a perspective view of an internal structure of the scanner unit 3. As shown in FIGS. 1 and 2, the scanner unit 3 includes an upper frame 11 that is a casing, an image reading portion 12 housed in the upper frame 11, and an upper cover 13 that is pivotably supported on top of the upper frame 11. The upper frame 11 includes a box-shaped lower case 16 that houses the image reading portion 12 and an upper case 17 that covers the top side of the lower case 16. A document placing plate (platen T: refer to FIG. 5) made of glass is provided over the upper case 17, and a medium to be read (document P: refer to FIG. 5) is placed on the document placing plate with the side to be read facing downward. On the other hand, the lower case 16 is formed to have a shallow box shape with its upper side being open.

As shown in FIG. 2, the image reading portion 12 includes a line sensor type sensor unit 31, a sensor carriage 32 incorporating the sensor unit 31, a guide shaft 33 that extends in the sub scanning direction Y and slidably supports the sensor carriage 32, and a self-propelled sensor moving mechanism 34 that moves the sensor carriage 32 along the guide shaft 33. The sensor unit 31 includes an image sensor module 41 that is constituted by a CMOS (complementary metal-oxide-semiconductor) line sensor extending in the main scanning direction X, and is moved back and forth along the guide shaft 33 in the sub scanning direction Y by the motor-driven sensor moving mechanism 34. Accordingly, the image on the medium to be read placed on the document placing plate is read. The sensor unit 31 may be constituted by a CCD (charge coupled device) line sensor.

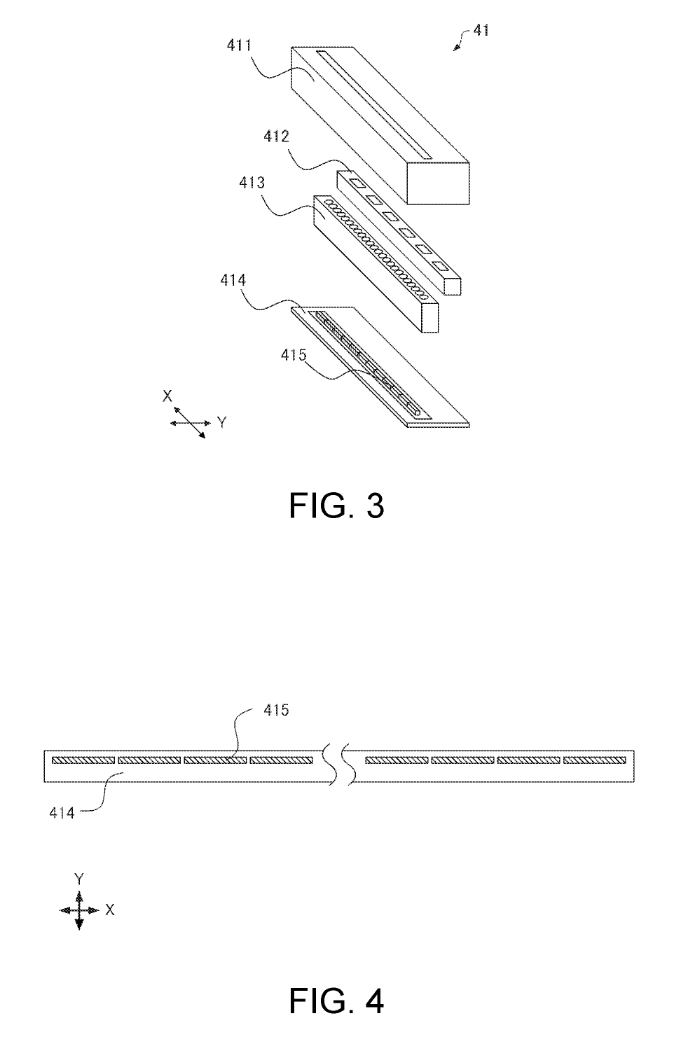

FIG. 3 is an exploded perspective view schematically illustrating a configuration of the image sensor module 41. In the example shown in FIG. 3, the image sensor module 41 includes a case 411, a light source 412, an optical portion 413, a module substrate 414, and an image reading chip 415 (semiconductor device) for reading an image. The light source 412, the optical portion 413, and the image reading chip 415 are housed between the case 411 and the module substrate 414. The case 411 is provided with a slit. The light source 412 emits light to a medium to be read. The light emitted by the light source 412 is incident on the medium to be read via the slit, and the light reflected from the medium to be read is input into the optical portion 413 via the slit. The optical portion 413 guides the input light to the image reading chips 415 so as to form a reduced image thereon.

FIG. 4 is a plan view schematically showing an arrangement of the image reading chip 415. As shown in FIG. 4, a plurality of image reading chips 415 are arranged side by side on the module substrate 414 in a unidimensional direction (the main scanning direction X in FIG. 4). Each image reading chip 415 includes a large number of photodetectors that are arranged in a line. The more densely the photodetectors are provided in each image reading chip 415, the higher image reading resolution of the scanner unit 3 (image reading device) can be achieved. Also, by providing a greater number of image reading chips 415, it is possible to realize a scanner unit 3 (image reading device) that can read a large image as well.

The image sensor module 41 and the optical portion 413 in the present embodiment will be described in detail using FIGS. 5 and 6.

FIG. 5 is a diagram illustrating an example of an optical path inside the image sensor module 41 in the present embodiment, and shows a state in which the line of sight is parallel to the main scanning direction X (cross-sectional view along the sub scanning direction Y). Note that broken lines in FIG. 5 show an example of the optical path of light emitted from the light source 412.

The optical portion 413 includes a plurality of reflecting mirrors 416 and a lens 417.

The light source 412 emits light to a document P. The lens 417 forms an image on the image reading chip 415 with light from the document P. The reflecting mirrors 416 are for increasing the length of the optical path of the reflected light in order for the lens 417 to form an image on the image reading chip 415 with light reflected from the document P. When the optical path cannot be increased, the angle of view increases. The image reading chip 415 outputs a signal according to the received light. Note that the arrangement and number of the reflecting mirrors 416 and the lens 417 in the optical portion 413 described in FIG. 5 are an example, and may be optimized according to the optical path and reduction ratio.

Also, FIG. 6 is a diagram illustrating an exemplary optical path inside the image sensor module 41 in the present embodiment, and shows a state in which the line of sight is parallel to the sub scanning direction Y (cross-sectional view along the main scanning direction X). Note that, in FIG. 6, the range of the optical path of light reflected from the document P that each of the image reading chips 415 (415-1 to 415-n) can receive is illustrated by adjacent broken lines or one dot chain lines.

In FIG. 6, the light reflected from the document P is guided to the image reading chips 415 via the optical portion 413. As described above, the plurality of image reading chips 415 (415-1 to 415-n) are arranged side by side in the main scanning direction X. Also, images of successive portions, in the main scanning direction X, of the document P are formed on the respective plurality of image reading chips 415 (415-1 to 415-n) while the images are partially overlapped and reduced by the optical portion 413.

That is, an image of a portion (example of “first partial image”) of the document P (example of “image”), the image being reduced by the optical portion 413 (example of “optical unit”), is formed on the image reading chip 415-1 (example of “first image reading chip”). Also, an image of another portion (example of “second partial image”) of the document P, the image being reduced by the optical portion 413, is formed on the image reading chip 415-2 (example of “second image reading chip”).

A reduced image of a portion of the document P is formed on each image reading chip 415 in the present embodiment via the optical portion 413. Therefore, photodetectors provided in the image reading chip 415 need not be arranged up to an end of the image reading chip 415. As a result, in the image reading chip 415 in the present embodiment, circuits can be arranged with less limitation due to the resolution and the number of pixels, and the space can be effectively utilized.

The image sensor module 41 in the present embodiment is realized by a so-called optical reduction system image reading method in which light from the light source 412 is emitted onto the document P, and an image is formed on the image reading chips 415 while the optical path length of the light reflected by the document P is secured and the image is reduced by the reflecting mirrors 416 and the lens 417 provided in the optical portion 413. That is, a large depth of field can be realized compared with an image reading device of a CIS (Contact Image Sensor) method. Also, since a plurality of image reading chips 415 are used, the reduction ratio of an image formed on each image reading chip 415 can be reduced relative to the image reading device of a known optical reduction system. Therefore, the optical path of light reflected from the document P can be reduced, and the size of the image sensor module 41 can be reduced. Note that the scanner unit 3 according to the present embodiment uses an image reading method in which data of a plurality of divided images generated by one image (document P) being divided and reduced is acquired by the plurality of image reading chips 415 (415-1 to 415-n), image processing is performed based on the data acquired by the plurality of image reading chips 415 (415-1 to 415-n), and as a result the one image (document P) is restored, which is referred to as a divided optical reduction system.

2. Functional Configuration of Image Reading Device

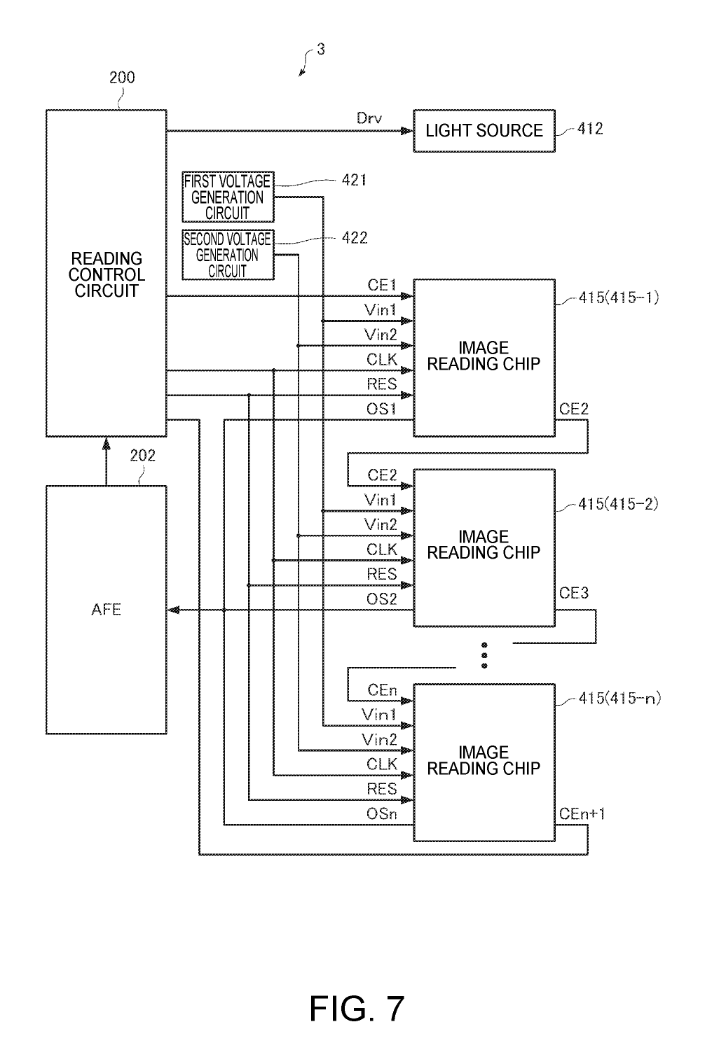

FIG. 7 is a diagram illustrating a functional configuration of the scanner unit 3. In the example shown in FIG. 7, the scanner unit 3 includes a reading control circuit 200, an analog front end (AFE) 202, the light source 412, the plurality of image reading chips 415 (415-1 to 415-n), a first voltage generation circuit 421, and a second voltage generation circuit 422. Also, the reading control circuit 200, the analog front end 202, the first voltage generation circuit 421, and the second voltage generation circuit 422 may be provided in the module substrate 414 or in an unshown substrate that is different from the module substrate 414. Also, the reading control circuit 200, the analog front end 202, the first voltage generation circuit 421, and the second voltage generation circuit 422 may each be realized by an integrated circuit (IC).

The reading control circuit 200 supplies a drive signal Drv in a fixed time period of exposure time Δt in each of a read period t of an image, so as to cause the light source 412 to emit light.

Also, the reading control circuit 200 supplies a clock signal CLK and a resolution setting signal RES to the plurality of image reading chips 415 in common. The clock signal CLK is an operation clock signal for the image reading chips 415, and the resolution setting signal RES is a signal for setting a resolution in reading of an image by the scanner unit 3. The resolution setting signal RES may be a 2-bit signal, which causes the resolution of 1200 dpi to be set when “00”, 600 dpi to be set when “01”, and 300 dpi to be set when “01”, for example.

The light source 412 emits light according to the drive signal Drv output from the reading control circuit 200. The light source 412 uses a white light source, and the white light source may include a single color light source and an unshown filter or the like, or may be constituted by red, green, and blue light sources.

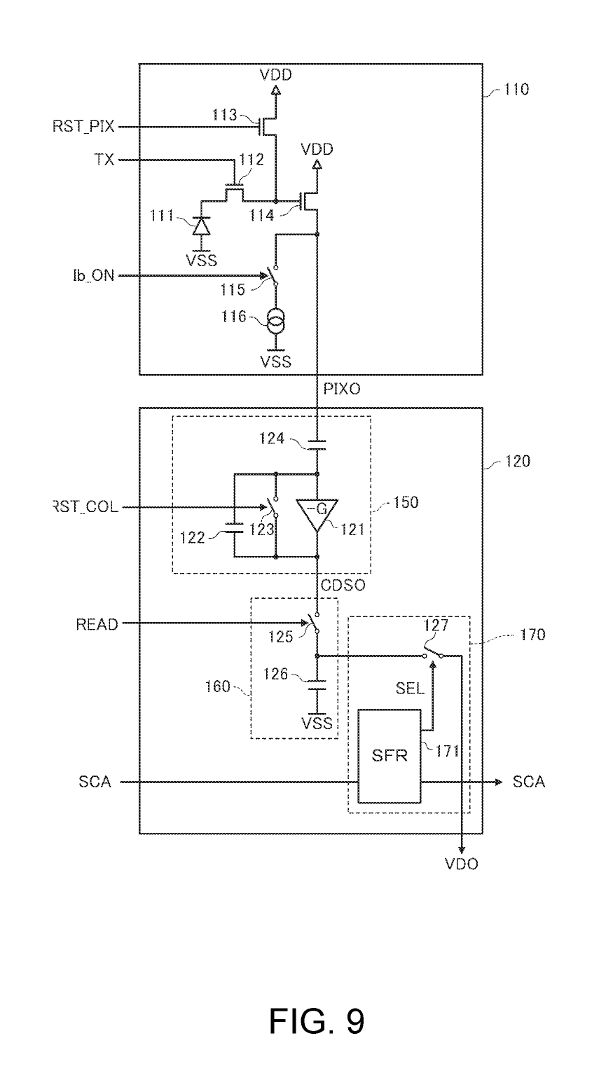

N chips of the image reading chips 415 (415-1 to 415-n) are arranged side by side on the module substrate 414. The image reading chips 415 operate in synchronization with the clock signal CLK when respective chip enable signals CEi (i=1 to n) are activated (high level, in the present embodiment). The image reading chips 415 (415-1 to 415-n) each detect light that was emitted by the light source 412 and reflected by a document P using photodetectors 111 (refer to FIG. 9), and convert the detected light to an electric signal. Then, the image reading chips 415 (415-1 to 415-n) respectively generate and output image signals OSi (i=1 to n) including image information based on the resolution set by the resolution setting signal RES.

The first voltage generation circuit 421 and the second voltage generation circuit 422 supply power for the image reading chips 415 (415-1 to 415-n) to operate.

The analog front end 202 receives the image signals OSi (i=1 to n) that are respectively output by the plurality of image reading chips 415 (415-1 to 415-n), performs amplification processing and A/D conversion processing on the received image signals OSi (i=1 to n), and converts the received image signals to digital signals each including a digital value according to the amount of light received by a photodetector 111. Then, the analog front end 202 sequentially transmits the digital signals to the reading control circuit 200.

The reading control circuit 200 receives the digital signals sequentially transmitted from the analog front end 202, and generates read image information of the image sensor module 41.

3. Electrical Configuration and Operation of Image Reading Chip

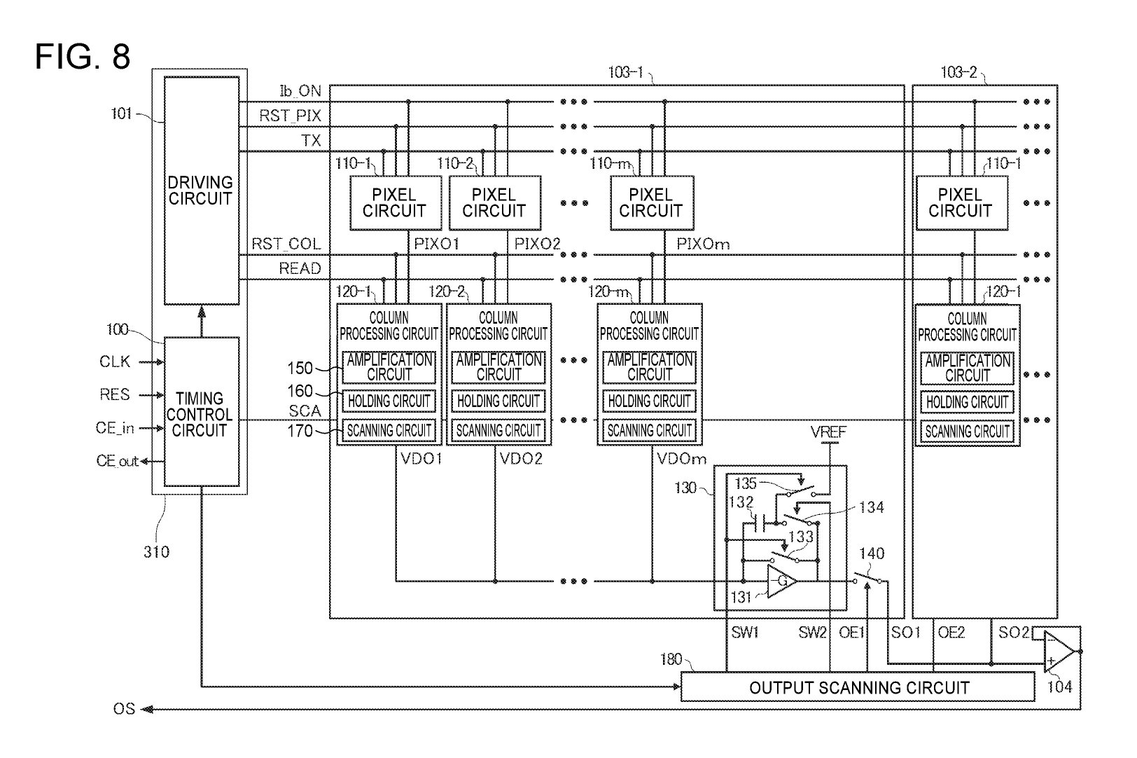

The electrical configuration and operation of the image reading chips 415 in the present embodiment will be described using FIGS. 8 to 10. Note that because the plurality of image reading chips 415 (415-1 to 415-n) that constitute the image sensor module 41 all have the same configuration, each image reading chip 415 will be described as an image reading chip 415 (example of “first image reading chip”). Also, the chip enable signals CEi (i=1 to n) respectively input to the image reading chips 415-i (i=1 to n) will each be described as a chip enable signal CE_in, and chip enable signals CEi+1 (i=1 to n) that are respectively output from the image reading chips 415-i (i=1 to n) will each be described as a chip enable signal CE_out. Also, image signals OSi (i=1 to n) respectively output from the image reading chips 415-i (i=1 to n) will each be described as an image signal OS.

FIG. 8 is a diagram illustrating a circuit configuration of the image reading chip 415. The image reading chip 415 shown in FIG. 8 includes a drive control circuit 310, two signal processing circuits 103-1 and 103-2, an operational amplifier 104, and an output scanning circuit 180. These circuits are supplied with a voltage Vin1, a voltage Vin2, and the ground potential that are input to unshown terminals of the image reading chip 415 so as to operate.

The drive control circuit 310 includes a timing control circuit 100 and a driving circuit 101.

The timing control circuit 100 includes an unshown counter that counts pulses of the clock signal CLK, and generates a control signal for controlling the operation of the driving circuit 101, a control signal for controlling the operation of the output scanning circuit 180, and a scan signal SCA for controlling the operations of a later-described scanning circuit 170 based on an output value (count value) of the counter.

Also, the timing control circuit 100, upon receiving an active chip enable signal CE_in, activates the operation of the image reading chip 415. Also, the timing control circuit 100, after completing the processing of the image reading chip 415 and outputting an active chip enable signal CE_out to the next image reading chip 415 or the reading control circuit 200 (refer to FIG. 7), deactivates the operation of the image reading chip 415.

The driving circuit 101 generates a bias current ON signal lb_ON, in synchronization with the clock signal CLK, that is activated (high level, in the present embodiment) during a fixed time period at a predetermined timing based on the control signal from the timing control circuit 100. This bias current ON signal lb_ON is supplied, in common, to m pixel circuits 110 (110-1 to 110-m) included in each of the two signal processing circuits 103-1 and 103-2.

Also, the driving circuit 101 generates a pixel reset signal RST_PIX and a column reset signal RST_COL, in synchronization with the clock signal CLK, that is activated (high level, in the present embodiment) during a fixed time period at a predetermined timing based on the control signal from the timing control circuit 100. This pixel reset signal RST_PIX is supplied, in common, to the m pixel circuits 110 (110-1 to 110-m) included in each of the two signal processing circuits 103-1 and 103-2. Also, the column reset signal RST_COL is supplied, in common, to m column processing circuits 120 (120-1 to 120-m) included in each of the two signal processing circuits 103-1 and 103-2.

Also, the driving circuit 101 generates a transfer signal TX and a readout signal READ, in synchronization with the clock signal CLK, that is activated (high level, in the present embodiment) during a fixed time period at a predetermined timing based on the control signal from the timing control circuit 100. The transfer signal TX is supplied, in common, to the m pixel circuits 110 (110-1 to 110-m) included in each of the two signal processing circuits 103-1 and 103-2. Also, the readout signal READ is supplied, in common, to the m column processing circuits 120 (120-1 to 120-m) included in each of the two signal processing circuits 103-1 and 103-2.

The two signal processing circuits 103-1 and 103-2 have the same configuration, and each include the m pixel circuits 110 (110-1 to 110-m), the m column processing circuits 120 (120-1 to 120-m), an amplification circuit 130, and a switch 140.

The m pixel circuits 110 (110-1 to 110-m) respectively output pixel signals PIXO1 to PIXOm each having a voltage corresponding to the amount of light received from a medium to be read during a period of exposure time Δt, due to light emitted by the light source 412.

For example, the pixel circuit 110-1 (example of “first pixel”) includes a photodetector 111 (refer to FIG. 9) (example of “first photodetector”) that receives light of a portion of an image reduced by the optical portion 413 and performs photoelectric conversion, amplifies a signal generated as a result of photoelectric conversion, and generates a pixel signal PIXO1 (example of “first pixel signal”). Also, the pixel circuit 110-2 (example of “second pixel”) includes a photodetector 111 (refer to FIG. 9) (example of “second photodetector”) that receives light of a different portion of the image reduced by the optical portion 413 and performs photoelectric conversion, amplifies a signal generated as a result of photoelectric conversion, and generates a pixel signal PIXO2 (example of “second pixel signal”).

The m column processing circuits 120 (120-1 to 120-m) each include an amplification circuit 150, a holding circuit 160, and a scanning circuit 170.

The m column processing circuits 120 (120-1 to 120-m) respectively amplify the pixel signals PIXO1 to PIXOm output from the m pixel circuits 110 (110-1 to 110-m) using the respective amplification circuits 150, and each store the amplified voltage in the holding circuit 160 according to the readout signal READ. Then, the column processing circuits 120 (120-1 to 120-m) sequentially output respective image signals VDO1 to VDOm based on the voltage stored in the respective holding circuits 160 to the amplification circuit 130 based on the scan signal SCA input to the scanning circuit 170.

That is, the column processing circuit 120-1 (example of “first readout circuit”) is electrically connected to the pixel circuit 110-1, and reads out the pixel signal PIXO1 from the pixel circuit 110-1. The amplification circuit 150 (example of “first amplification circuit”) included in the column processing circuit 120-1 amplifies the pixel signal PIXO1. The scanning circuit 170 (example of “first scanning circuit”) included in the column processing circuit 120-1 controls the readout timing of the image signal VDO1 (example of “first readout signal”) that is generated by the pixel signal PIXO1 being amplified by the amplification circuit 150.

Also, the column processing circuit 120-2 (example of “second readout circuit”) is electrically connected to the pixel circuit 110-2, and reads out the pixel signal PIXO2 from the pixel circuit 110-2. The amplification circuit 150 (example of “second amplification circuit”) included in the column processing circuit 120-2 amplifies the pixel signal PIXO2. The scanning circuit 170 (example of “second scanning circuit”) included in the column processing circuit 120-2 controls the output timing of the image signal VDO2 (example of “second readout signal”) that is generated by the pixel signal PIXO2 being amplified by the amplification circuit 150.

Here, in the present embodiment, the scanning circuits 170 respectively included in the m column processing circuits 120 (120-1 to 120-m) sequentially operate according to the scan signal SCA input from the timing control circuit 100. Specifically, each scanning circuit 170 includes a shift register, for example. For example, when the scan signal SCA is input to the scanning circuit 170 included in the column processing circuit 120-j (j=1 to m−1), the column processing circuit 120-j (j=1 to m−1) outputs the image signal VDOj (j=1 to m−1) to the amplification circuit 130, and outputs the scan signal SCA to the column processing circuit 120-j+1 (j=1 to m−1). The scan signal SCA is input to the scanning circuit 170 included in the column processing circuit 120-j+1 (j=1 to m−1), and the column processing circuit 120-j+1 (j=1 to m−1) outputs the image signal VDOj+1 (j=1 to m−1) to the amplification circuit 130.

In the present embodiment, the scan signal SCA is input such that the timing at which the image signal VDO1 is output by the scanning circuit 170 included in the column processing circuit 120-1 is earlier than the timing at which the image signal VDO2 is output by the scanning circuit 170 included in the column processing circuit 120-2.

The amplification circuit 130 includes an operational amplifier 131, a capacitor 132, and switches 133 to 135.

The operational amplifier 131 is a grounded source amplifier constituted by a plurality of MOS transistors, for example. The capacitor 132 is a feedback capacitor of the operational amplifier 131. The switch 133 is a feedback switch of the operational amplifier 131. The switch 134 is a feedback signal control switch of the operational amplifier 131. The switch 135 is an external input signal control switch of the operational amplifier 131.

One end of the switch 133 and one end of the capacitor 132 is connected to an input terminal of the operational amplifier 131. The other end of the capacitor 132 is connected to one end of the switch 134 and one end of the switch 135.

The other end of the switch 133 and the other end of the switch 134 are connected to an output terminal of the operational amplifier 131. A reference voltage VREF is applied to the other end of the switch 135. The reference voltage VREF may be generated by a voltage generator that is not shown in FIG. 8, or may be supplied from an external terminal of the image reading chip 415.

A switch control signal SW1 from the output scanning circuit 180 is commonly input to a control terminal of the switch 133 and a control terminal of the switch 135, and the switches 133 and 135 are turned on when the switch control signal SW1 is activated (high level, in the present embodiment). Also, a switch control signal SW2 from the output scanning circuit 180 is input to a control terminal of the switch 134, and the switch 134 is turned on when the switch control signal SW2 is activated (high level, in the present embodiment). The switch control signal SW1 and the switch control signal SW2 are exclusively activated (high level, in the present embodiment).

Output enable signals OE1 and OE2 from the output scanning circuit 180 are respectively input to control terminals of the switches 140 respectively included in the two signal processing circuits 103-1 and 103-2. The switches 140 included in the two signal processing circuits 103-1 and 103-2 are respectively turned on when the respective output enable signals OE1 and OE2 are activated (high level, in the present embodiment).

The output enable signals OE1 and OE2 are signals only one of which is sequentially activated (high level), and the two signal processing circuits 103-1 and 103-2 sequentially output image signals SO1 and SO2 from the amplification circuits 130 via the switches 140, respectively.

The operational amplifier 104 generates an image signal OS to be output to the outside of the image reading chip 415-1.

Output terminals (other ends of respective switches 140) of the two signal processing circuits 103-1 and 103-2 are commonly connected to a non-inverting input terminal of the operational amplifier 104, and an inverting input terminal is connected to an output terminal thereof. This operational amplifier 104 is configured as a voltage follower, and the output voltage matches the voltage at the non-inverting input terminal. Accordingly, the output signal of the operational amplifier 104 is a signal that sequentially includes the image signals SO1 and SO2, and is output as an image signal OS from the image reading chip 415.

The m pixel circuits 110 (110-1 to 110-m) shown in FIG. 8 all have the same configuration. Similarly, the m column processing circuits 120 (120-1 to 120-m) all have the same configuration. Therefore, each of them pixel circuits 110 (110-1 to 110-m) will be described in detail as a pixel circuit 110, and each of the m column processing circuits 120 (120-1 to 120-m) will be described in detail as a column processing circuit 120, using FIG. 9.

FIG. 9 is a diagram illustrating a circuit configuration of the pixel circuit 110 and the column processing circuit 120. As shown in FIG. 9, the pixel circuit 110 includes the photodetector 111, a transfer gate 112, NMOS transistors 113 and 114, a switch 115, and a constant current source 116.

The photodetector 111 converts (photoelectric conversion) the received light (light from an image formed in the medium to be read, in the present embodiment) to an electric signal. In the present embodiment, the photodetector 111 is constituted by a photodiode whose anode is supplied with a ground potential VSS and whose cathode is connected to one end of the transfer gate 112.

The transfer signal TX is input to a control terminal of the transfer gate 112, and the other end of the transfer gate 112 is connected to a gate terminal of the NMOS transistor 114.

The NMOS transistor 113 has a drain terminal supplied with a power supply potential VDD, a gate terminal to which the pixel reset signal RST_PIX is input, and a source terminal connected to the gate terminal of the NMOS transistor 114.

A drain terminal of the NMOS transistor 114 is supplied with the power supply potential VDD, and a source terminal of the NMOS transistor 114 is connected to one end of the switch 115.

The other end of the switch 115 is connected to one end of the constant current source 116, the other end of the constant current source 116 is supplied with the ground potential VSS. Also, the bias current ON signal lb_ON is input to a control terminal of the switch 115. The switch 115 is a switch having a function of controlling a load current for driving the NMOS transistor 114, and turns on when the bias current ON signal lb_ON is activated (high level, in the present embodiment), and as a result, the source terminal of the NMOS transistor 114 is electrically connected to the one end of the constant current source 116. The signal output from the source terminal of the NMOS transistor 114 is input to the column processing circuit 120 as the pixel signal PIXO (one of PIXO1 to PIXOm in FIG. 8).

The column processing circuit 120 includes the amplification circuit 150, the holding circuit 160, and the scanning circuit 170.

The amplification circuit 150 includes an inverting amplifier 121, a capacitor 122, a switch 123, and a capacitor 124.

The capacitor 124 has one end connected to the source terminal (output terminal of the pixel circuit 110) of the NMOS transistor 114 in the pixel circuit 110, and the other end is connected to an input terminal of the inverting amplifier 121.

The inverting amplifier 121 is a grounded source amplifier constituted by a plurality of MOS transistors, for example. The capacitor 122 is a feedback capacitor of the inverting amplifier 121. The switch 123 is a feedback switch of the inverting amplifier 121. One end of the capacitor 122 and one end of the switch 123 are connected to the input terminal of the inverting amplifier 121, and the other end of the capacitor 122 and the other end of the switch 123 are connected to an output terminal of the inverting amplifier 121.

The column reset signal RST_COL is input to a control terminal of the switch 123, and the switch 123 is turned on when the column reset signal RST_COL is activated (high level, in the present embodiment).

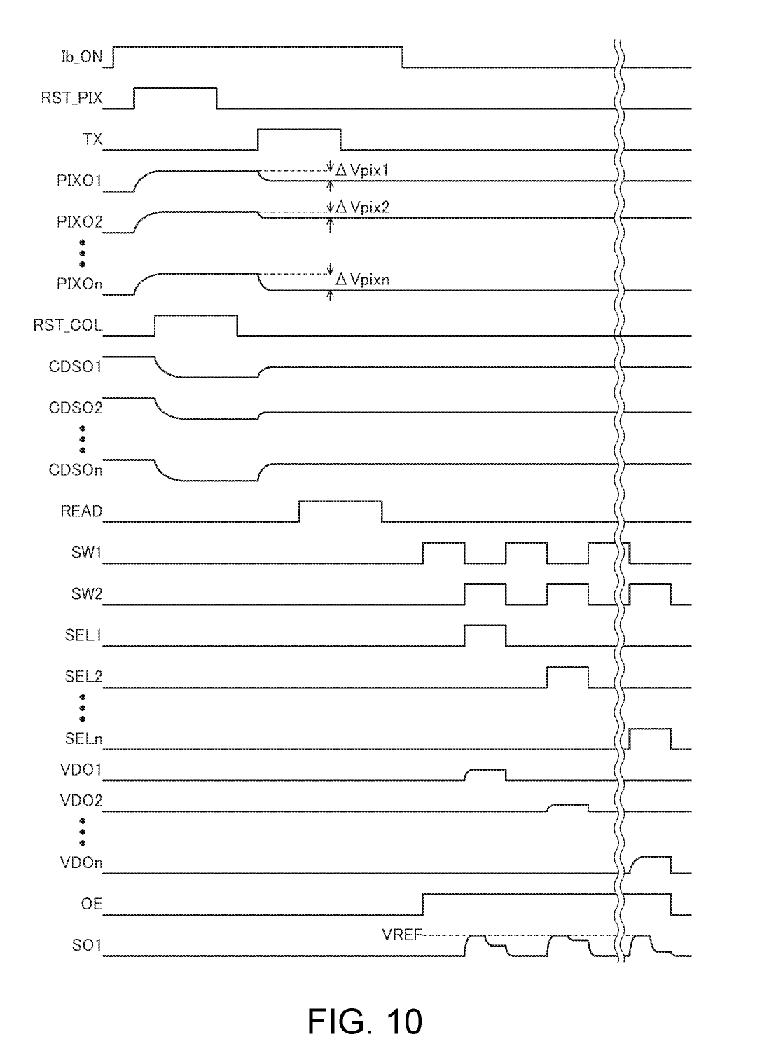

That is, a CDS (Correlated Double Sampling) circuit is configured by the inverting amplifier 121, the capacitor 122, the switch 123, and the capacitor 124, in the amplification circuit 150. The amplification circuit 150 has a function of cancelling noise in an output voltage Vpix (refer to FIG. 10) from the pixel circuit 110 using the capacitor 124 and performing amplification thereon. The voltage at the output terminal of the inverting amplifier 121 is an output signal CDSO of the amplification circuit 150.

The holding circuit 160 includes a switch 125 and a capacitor 126.

One end of the switch 125 is connected to the output terminal (output terminal of the amplification circuit 150) of the inverting amplifier 121 included in the amplification circuit 150. The other end of the switch 125 is connected to one end of the capacitor 126. The other end of the capacitor 126 is supplied with the ground potential VSS. The readout signal READ is input to a control terminal of the switch 125, and the switch 125 is turned on when the readout signal READ is activated (high level, in the present embodiment), and as a result, the output terminal of the inverting amplifier 121 is electrically connected to the one end of the capacitor 126. Accordingly, charges corresponding to the potential difference between the output signal CDSO of the amplification circuit 150 and the ground potential VSS are accumulated (held) in the capacitor 126.

The scanning circuit 170 includes a switch 127 and a shift register (SFR) 171.

One end of the switch 127 is connected to the one end of the capacitor 126 included in the holding circuit 160, and the other end of the switch 127 is connected to the operational amplifier 131 (input terminal of the amplification circuit 130) included in the amplification circuit 130 (refer to FIG. 8). Also, a selection signal SEL is input to a control terminal of the switch 127. The switch 127 is a column selection switch, is turned on when the selection signal SEL is activated (high level, in the present embodiment), and as a result, the one end of the capacitor 126 is electrically connected to the input terminal (input terminal of the amplification circuit 130) of the operational amplifier 131. A signal (signal having a voltage corresponding to the charges accumulated in the capacitor 126) at the one end of the capacitor 126 is input to the amplification circuit 130 as an image signal VDO (one of VDO1 to VDOm in FIG. 8).

The shift register 171 outputs a selection signal SEL for controlling the switch 127 based on the input scan signal SCA. Then, the shift register 171 transfers the scan signal SCA to the adjacent scanning circuit 170 included in the column processing circuit 120-i+1 (i=1 to m−1).

That is, the scanning circuits 170 sequentially output, based on the respective scan signals SCA, the signals (signals each having a voltage corresponding to the charges accumulated in the capacitor 126) held in the respective holding circuits 160 in the column processing circuits 120-1 to 120-m to the amplification circuit 130.

FIG. 10 is a timing chart illustrating operation timings of the signal processing circuit 103-1 shown in FIG. 8. Note that charges (negative charges) corresponding to the amount of received light are assumed to be accumulated in the photodetector 111 included in each of them pixel circuits 110 (110-1 to 110-m).

As shown in FIG. 10, first, the bias current ON signal lb_ON is activated (high level, in the present embodiment), and the switch 115 is turned on in each of them pixel circuits 110. When the pixel reset signal RST_PIX is activated (high level, in the present embodiment) in this state, the NMOS transistor 113 is turned on, and the power supply potential VDD is supplied to the gate terminal of the NMOS transistor 114, in each of them pixel circuits 110. Accordingly, the gate potential of the NMOS transistor 114 is reset, and the voltages of the pixel signals PIXO1 to PIXOm that are respectively output from the m pixel circuits 110 take values when the pixels are reset. At this time, because the column reset signal RST_COL is activated (high level), the switch 123 is turned on, and the charges accumulated in the capacitor 122 are discharged (the capacitor 122 is reset), in each of them column processing circuits 120, and the voltages of the output signals CDSO1 to CDSOm of the m amplification circuits 150 decrease to a predetermined voltage.

Next, after the pixel reset signal RST_PIX and the column reset signal RST_COL are deactivated (low level), the transfer signal TX is activated (high level), and therefore, in each of the m pixel circuits 110, and the voltage corresponding to the charges accumulated in the photodetector 111 is applied to the gate terminal of the NMOS transistor 114. The larger the amount of light received by each photodetector 111, the larger the amount of charges (negative charges) accumulated in the photodetector 111, and therefore the voltage of the corresponding gate terminal of the NMOS transistor 114 decreases.

Accordingly, the voltages of the pixel signals PIXO1 to PIXOm respectively decrease by ΔVpix1 to ΔVpixm. At this time, since the switch 123 is turned off, the m amplification circuits 150 operate, and the output signals CDSO1 to CDSOm increase in proportion to ΔVpix1 to ΔVpixm, respectively.

Next, after the voltages of the output signals CDSO1 to CDSOm of the m amplification circuits 150 are stabilized, when the readout signal READ is activated (high level, in the present embodiment), the switches 125 are turned on, and charges accumulated in the m capacitors 126 change according to ΔVpix1 to ΔVpixm, respectively.

Next, after the bias current ON signal lb_ON, the transfer signal TX, and the readout signal READ are deactivated (low level, in present embodiment), an output enable signal OE (OE1 or OE2 in FIG. 8) is activated (high level, in the present embodiment) for a fixed period of time. Also, while the output enable signal OE is activated (high level, in the present embodiment), a state in which the switch control signal SW1 is activated (high level, in the present embodiment) and the switch control signal SW2 is deactivated (low level, in present embodiment) and a state in which the switch control signal SW1 is deactivated (low level) and the switch control signal SW2 is activated (high level, in the present embodiment) are alternatingly repeated. Also, every time the switch control signal SW1 is deactivated (low level, in present embodiment) and the switch control signal SW2 is activated (high level, in the present embodiment), m selection signals SEL (SEL1 to SELm), which are respectively controlled by the scanning circuits 170 provided in the m column processing circuits 120 (120-1 to 120-m), are sequentially activated (high level, in the present embodiment).

Then, every time the m selection signals SEL (SEL1 to SELm) are sequentially activated (high level, in the present embodiment), the image signals VDO1 to VDOm respectively having voltages corresponding to the charges accumulated in the capacitors 126 are sequentially output from the m column processing circuits 120 (120-1 to 120-m). The image signals VDO1 to VDOm are sequentially amplified by the amplification circuit 130, and as a result, the image signal SO1 is generated.

The timing chart illustrating the operation timings of the signal processing circuit 103-2 shown in FIG. 8 is similar to those shown in FIG. 10, and therefore the illustration and description thereof are omitted.

The image signal SO1 (or SO2) generated in the signal processing circuit 103-1 (or 103-2) is output from the image reading chip 415 as the image signal OS, which is the output signal of the operational amplifier 104.

4. Circuit Layout of Image Reading Chip

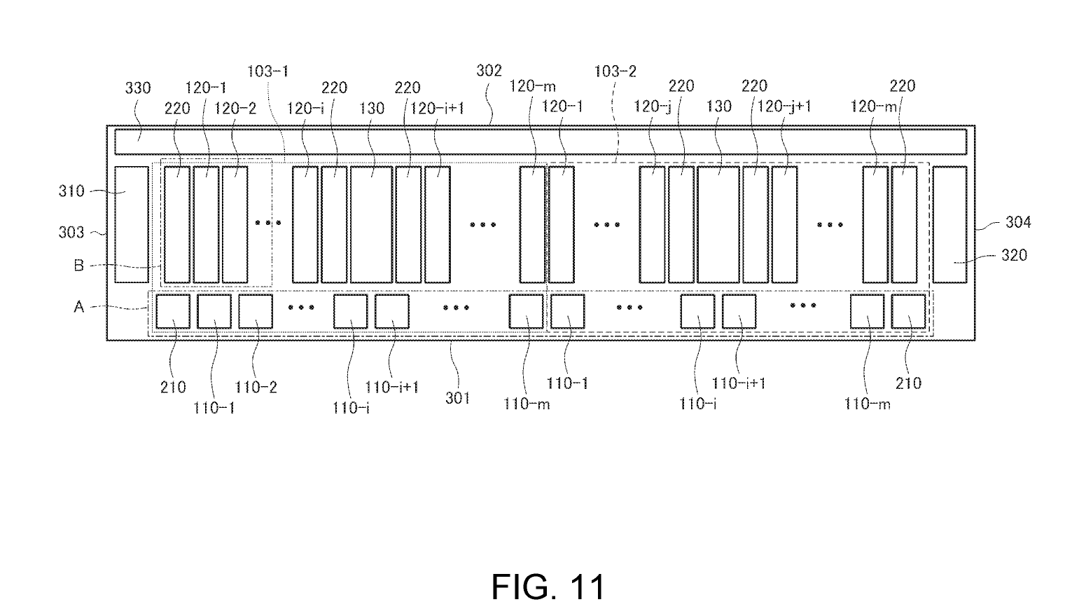

FIG. 11 is a diagram schematically illustrating a circuit layout of the image reading chip 415 in the present embodiment.

The image reading chip 415 is formed in a silicon substrate 300 having a substantially rectangular shape including a long side 301 (example of “first side”), a long side 302, a short side 303 (example of “second side”) that is shorter than the long side 301, and a short side 304. Note that description will be given defining the direction from the short side 303 toward the short side 304, that is the direction in which the long side 301 extends, as a long side direction x, and the direction from the long side 301 toward the long side 302, that is, the direction in which the short side 303 extends, as a short side direction y.

The image reading chip 415 includes the two signal processing circuits 103-1 and 103-2, the drive control circuit 310, a voltage generation circuit 320, and an input/output portion 330. Note that the constituent elements included in the image reading chip 415 described above are electrically connected by unshown interconnects. In the present embodiment, the circuits that constitute the image reading chip 415 are integrally formed on the silicon substrate 300 using semiconductor processing including photolithography. That is, the image reading chip 415 is configured as one IC (Integrated Circuit) chip.

The two signal processing circuits 103-1 and 103-2 are provided adjacent to each other along the long side direction x, the signal processing circuit 103-1 is formed on the short side 303 side, and the signal processing circuit 103-2 is formed on the short side 304 side.

The two signal processing circuits 103-1 and 103-2 each include m pixel circuits 110-1 to 110-m, m column processing circuits 120-1 to 120-m, a dummy pixel circuit 210 (example of “pseudo pixel”), a plurality of dummy column processing circuits 220, and the amplification circuit 130. Note that the dummy pixel circuit 210 and the dummy column processing circuits 220 are constituent elements that do not contribute to reading of the document P (image), in the scanner unit 3, which will be described in detail later, and may be configured so as to not be electrically connected to other circuits, for example, or may be configured to not receive input of one or a plurality of various control signals (in the present embodiment, bias current ON signal lb_ON, transfer signal TX, readout signal READ, scan signal SCA, pixel reset signal RST_PIX, and column reset signal RST_COL), for example.

The m pixel circuits 110 (110-1 to 110-m) included in the signal processing circuit 103-1 are provided side by side in the long side direction x along the long side 301, and the dummy pixel circuit 210 is provided on the short side 303 side of them pixel circuits 110 (110-1 to 110-m) that are provided side by side.

That is, the pixel circuit 110-1, the pixel circuit 110-2, and the dummy pixel circuit 210 that are included in the signal processing circuit 103-1 are arranged side by side along the direction in which the long side 301 extends, and the distance between the dummy pixel circuit 210 and the short side 303 is shorter than the distance between the pixel circuit 110-1 included in the signal processing circuit 103-1 and the short side 303, and is shorter than the distance between the pixel circuit 110-2 included in the signal processing circuit 103-1 and the short side 303.

The m pixel circuits 110 (110-1 to 110-m) included in the signal processing circuit 103-2 are provided side by side in the long side direction x in succession to the pixel circuits 110 (110-1 to 110-m) in the signal processing circuit 103-1, and the dummy pixel circuit 210 is provided on the short side 304 side of the m pixel circuits 110 (110-1 to 110-m) that are provided side by side.

That is, the 2 m pixel circuits 110 included in the two signal processing circuits 103-1 and 103-2 are provided side by side along the long side 301 of the silicon substrate 300 from the short side 303 side toward the short side 304. Also, the dummy pixel circuits 210 are respectively provided at an end portion on the short side 303 side and an end portion on the short side 304 side of the 2 m pixel circuits 110 that are provided side by side. In other words, the dummy pixel circuits 210 are respectively provided side by side with the 2 m pixel circuits 110 included in the two signal processing circuits 103-1 and 103-2 that are provided side by side, at the end portions on the short side 303 side and the short side 304 side thereof.

Note that the 2 m pixel circuits 110 and the two dummy pixel circuits 210 included in the two signal processing circuits 103-1 and 103-2 need only be provided side by side in the long side direction x, and may be provided along the long side 302, for example, or may be provided side by side in the long side direction x at a middle portion of the long side 301 and the long side 302.

As a result of providing the dummy pixel circuit 210 that is not involved in reading of an image at the end portions of the 2 m pixel circuits 110 that are provided side by side in this way, variations in characteristics in the pixel circuits 110 in the manufacturing process can be reduced. Here, the variations in characteristics in the manufacturing process refer to a variation due to the processing accuracy in a process of etching an oxide film and a variation in the concentration of ions implanted as impurities, for example.

In the present embodiment, the image reading chip 415 is formed in the silicon substrate 300. The photoelectric conversion is also performed in the silicon substrate 300 similarly to the photodetector 111 used in the present embodiment. The electrons generated based on the photoelectric conversion performed in the silicon substrate 300 are detected by the photodetector 111. That is, it is possible that the photodetector 111 will convert not only light from the image formed on the medium to be read, but also electrons generated in the photoelectric conversion in the silicon substrate 300 to an electric signal.

In the present embodiment, the dummy pixel circuits 210 that are not involved in reading of an image are provided at both ends of the 2 m pixel circuit 110, and as a result, the electrons generated in the silicon substrate 300 can be guided to the dummy pixel circuits 210. Therefore, the photodetectors 111 that are involved in reading of an image can perform photoelectric conversion to generate an electric signal based only on the light from an image formed on the medium to be read. Therefore, the dummy pixel circuit 210 preferably includes a photodetector. It is further preferable if the dummy pixel circuit 210 is configured similarly to the pixel circuit 110 in order to suppress the influence of variations in manufacturing.

Furthermore, in the present embodiment, the 2 m pixel circuits 110 and the dummy pixel circuits 210 are formed in a region surrounded by the same N-well 283.

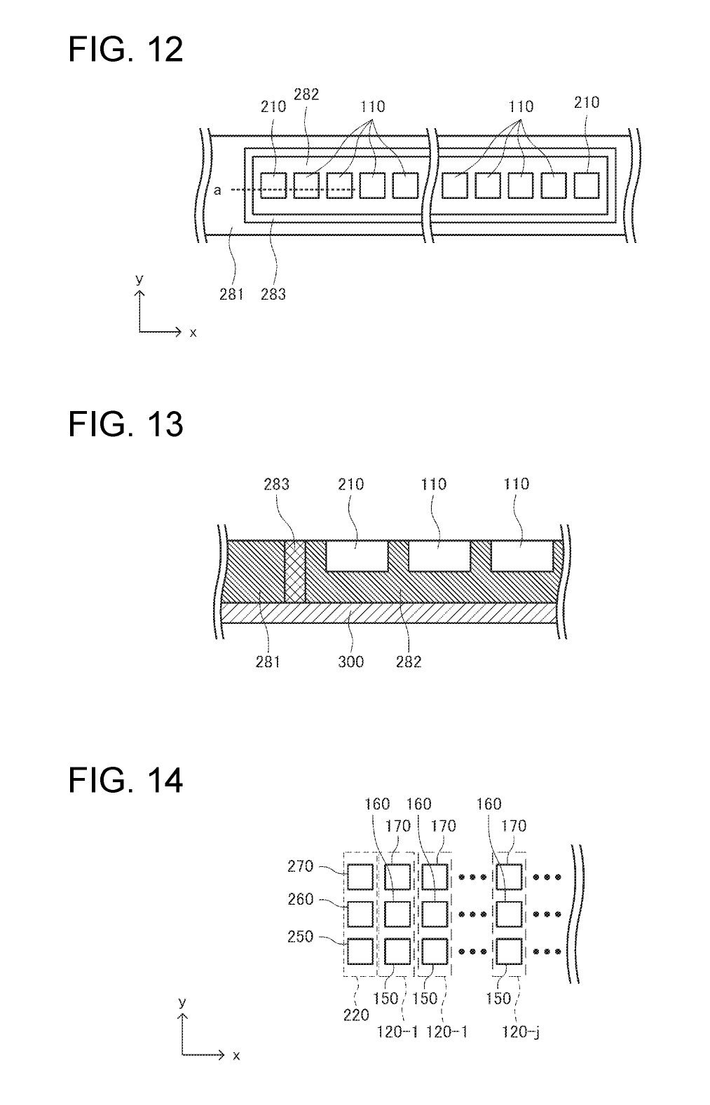

FIG. 12 is a diagram illustrating a detailed configuration of the 2 m pixel circuits 110 and the dummy pixel circuits 210 in the present embodiment, and is a diagram illustrating a portion A in FIG. 11. Also, FIG. 13 is a cross-sectional diagram taken along line a in FIG. 12. Here, x and y in FIGS. 12 and 13 indicate the same directions as in FIG. 11. Also, in FIGS. 12 and 13, P-wells 281 and 282 are connected to an unshown ground potential interconnect, and an N-well 283 is connected to an unshown power supply potential interconnect.

The 2 m pixel circuits 110 and the dummy pixel circuits 210 are formed in the same P-well 282. The P-well 282 is surrounded by the N-well 283 (example of “the same well”). That is, the P-well 281 provided in the silicon substrate 300 is isolated by the N-well 283 from the P-well 282 in which the 2 m pixel circuits 110 and the dummy pixel circuits 210 are formed.

Accordingly, the electrons generated by photoelectric conversion in a region (P-well 281 side, in the present embodiment) outside the region surrounded by the N-well 283 are absorbed by the N-well 283, which is at the power supply potential, and are unlikely to enter the region of the P-well 282 in which the 2 m pixel circuits 110 and the dummy pixel circuits 210 are provided. Therefore, the photodetectors 111 involved in reading of an image can convert light from the image formed on the medium to be read to an electric signal with high sensitivity, and the image reading accuracy can further be improved.

Returning to FIG. 11, them column processing circuits 120 (120-1 to 120-m) included in the signal processing circuit 103-1 are provided side by side on the long side 302 side of the m pixel circuits 110 (110-1 to 110-m), and the dummy column processing circuit 220 is provided on the short side 303 side of the m column processing circuits 120 (120-1 to 120-m) that are provided side by side.

The m column processing circuits 120 (120-1 to 120-m) included in the signal processing circuit 103-2 are provided side by side on the long side 302 side of the m pixel circuits 110 (110-1 to 110-m), and the dummy column processing circuit 220 is provided on the short side 304 side of the m column processing circuits 120 (120-1 to 120-m) that are provided side by side.

That is, the 2 m column processing circuits 120 included in the two signal processing circuits 103-1 and 103-2 are provided side by side along the long side direction x from the short side 303 side toward the short side 304. Also, the dummy column processing circuits 220 are respectively provided at the end portions on the short side 303 side and the short side 304 side of the 2 m column processing circuits 120 that are provided side by side. In other words, the dummy column processing circuits 220 are respectively provided at the end portions on the short side 303 side and the short side 304 side of the 2 m column processing circuits 120, side by side therewith, included in the two signal processing circuits 103-1 and 103-2 that are provided side by side.

As a result of providing the dummy column processing circuits 220 that are not involved in reading of an image at the end portions of the 2 m column processing circuits 120 that are provided side by side, variations in characteristics of the column processing circuit 120 in the manufacturing process can be reduced. Here, the variations in characteristics in the manufacturing process refer to a variation due to the processing accuracy in a process of etching an oxide film and a variation in the concentration of ions implanted as impurities, for example.

The amplification circuit 130 is provided side by side with some of the m column processing circuits 120 (120-1 to 120-m) that are provided side by side in the direction from the short side 303 to the short side 304. Specifically, the amplification circuit 130 is provided between a column processing circuit 120-j (j=1 to m−1) and a column processing circuit 120-j+1 (j=1 to m−1). As a result of providing the amplification circuit 130 and the m column processing circuits 120 (120-1 to 120-m) side by side in this way, the area of the silicon substrate 300 in the image reading chip 415 can be effectively utilized, and the chip size of the image reading chip 415 can be reduced.

Here, variations in characteristics of the column processing circuits 120 that are provided side by side can be suppressed, as a result of providing the dummy column processing circuits 220 at the respective end portions of the 2 m column processing circuits 120. That is, it is preferable that the dummy column processing circuits 220 are provided at both ends of the amplification circuit 130 that is provided side by side with some of them column processing circuits 120 (120-1 to 120-m) that are provided side by side.

Specifically, in the present embodiment, a dummy column processing circuit 220 is provided between a column processing circuit 120-i (i=1 to m−1) and the amplification circuit 130, and furthermore, a dummy column processing circuit 220 is also provided between a column processing circuit 120-i+1 (i=1 to m−1) and the amplification circuit 130. That is, it is preferable that a dummy column processing circuit 220 is provided, when different circuit elements are provided side by side, between the different circuit elements.

FIG. 14 is a diagram illustrating a detailed configuration of the column processing circuits 120 and the dummy column processing circuit 220, and is a diagram illustrating a portion B in FIG. 11.

As described above, the m column processing circuits 120 (120-1 to 120-m) each include the amplification circuit 150, the holding circuit 160, and the scanning circuit 170. Also, the dummy column processing circuit 220 includes a dummy amplification circuit 250, a dummy holding circuit 260, and a dummy scanning circuit 270, as shown in FIG. 14. Note that, since the dummy column processing circuit 220 is not involved in reading of the document P, the dummy amplification circuit 250, the dummy holding circuit 260, and the dummy scanning circuit 270 are also not involved in reading of the document P.

The amplification circuit 150 is provided on the pixel circuit 110 side in each column processing circuit 120. Also, the holding circuit 160 is provided on the long side 302 side of the amplification circuit 150, and the scanning circuit 170 is provided on the long side 302 side of the holding circuit 160. That is, in the column processing circuit 120, the amplification circuit 150, the holding circuit 160, and the scanning circuit 170 are provided in this order along the short side direction y.

The dummy amplification circuit 250 (example of “pseudo amplification circuit”) is provided on the dummy pixel circuit 210 side in the dummy column processing circuit 220. Also, the dummy holding circuit 260 is provided on the long side 302 side of the dummy amplification circuit 250, and the dummy scanning circuit 270 (example of “pseudo scanning circuit”) is provided on the long side 302 side of the dummy holding circuit 260. That is, in the dummy column processing circuit 220, the dummy amplification circuit 250, the dummy holding circuit 260, and the dummy scanning circuit 270 are provided in this order along the short side direction y.

Also, as described above, the dummy column processing circuit 220 is provided at the end portion of the column processing circuits 120 in the long side direction x.

Accordingly, the 2 m amplification circuits 150 are provided side by side along the long side direction x on the long side 302 side of the 2 m pixel circuits 110 (110-1 to 110-m) that are provided side by side. Also, the dummy amplification circuit 250 is provided at the end portion on the short side 303 side of the 2 m amplification circuits 150 that are provided side by side. That is, the amplification circuit 150 included in the column processing circuit 120-1, the amplification circuit 150 included in the column processing circuit 120-2, and the dummy amplification circuit 250 are provided side by side along the long side direction x, and the distance between the dummy amplification circuit 250 and the short side 303 is shorter than the distance between the amplification circuit 150 included in the column processing circuit 120-1 and the short side 303, and is shorter than the distance between the amplification circuit 150 included in the column processing circuit 120-2 and the short side 303.

Also, the 2 m holding circuits 160 are provided side by side in a direction from the short side 303 toward the short side 304 on the long side 302 side of the 2 m amplification circuits 150 that are provided side by side. Also, the dummy holding circuit 260 is provided at the end portion on the short side 303 side of the 2 m holding circuits 160 that are provided side by side. That is, the holding circuit 160 included in the column processing circuit 120-1, the holding circuit 160 included in the column processing circuit 120-2, and the dummy holding circuit 260 are provided side by side along the long side direction x, and the distance between the dummy holding circuit 260 and the short side 303 is shorter than the distance between the holding circuit 160 included in the column processing circuit 120-1 and the short side 303, and is shorter than the distance between the holding circuit 160 included in the column processing circuit 120-2 and the short side 303.

Also, the 2 m scanning circuits 170 are provided side by side in a direction from the short side 303 toward the short side 304 on the long side 302 side of the 2 m holding circuits 160 that are provided side by side. Also, the dummy scanning circuit 270 is provided at the end portion on the short side 303 side of the 2 m scanning circuits 170 that are provided side by side. That is, the scanning circuit 170 included in the column processing circuit 120-1, the scanning circuit 170 included in the column processing circuit 120-2, and the dummy scanning circuit 270 are arranged along the long side direction x, and the distance between the dummy scanning circuit 270 and the short side 303 is shorter than the distance between the scanning circuit 170 included in the column processing circuit 120-1 and the short side 303, and is shorter than the distance between the scanning circuit 170 included in the column processing circuit 120-2 and the short side 303.

That is, constituent elements (dummies) that are not involved in reading of the document P are included in the respective constituent elements included in the column processing circuit 120. Therefore, in each of the amplification circuit 150, the holding circuit 160, and the scanning circuit 170, variations in characteristics in the manufacturing process can further be reduced. Note that, the dummy column processing circuit 220 may be configured to include only one of the constituent elements included in a column processing circuit 120, or may be configured to include a plurality of the constituent elements. For example, the dummy column processing circuit 220 may be configured to include the dummy amplification circuit 250 and the dummy scanning circuit 270, and to not include the dummy holding circuit 260. Note that the variations in characteristics of the column processing circuit 120 in the manufacturing process have a large influence on the analog signal. Therefore, it is preferable that the dummy amplification circuit 250 corresponding to the amplification circuit 150 that amplifies and output an analog signal is included.

In FIG. 14, an example in which the dummy column processing circuit 220 is provided on the short side 303 side of the column processing circuits 120 side by side therewith has been described. In the case where the dummy column processing circuit 220 is provided on the short side 304 side of the column processing circuits 120 side by side therewith as well, for example, the amplification circuits 150 and the dummy amplification circuit 250 are provided side by side along the long side 301, the holding circuits 160 and the dummy holding circuit 260 are provided side by side along the long side 301, and the scanning circuits 170 and the dummy scanning circuit 270 are provided side by side along the long side 301.

Also, in the case where the dummy column processing circuit 220 is provide between the column processing circuit 120 and the amplification circuit 130 side by side therewith as well, the amplification circuits 150 and the dummy amplification circuit 250 are provided side by side along the long side 301, the holding circuits 160 and the dummy holding circuit 260 are provided side by side along the long side 301, and the scanning circuits 170 and the dummy scanning circuit 270 are provided side by side along the long side 301.

The drive control circuit 310 is provide on the short side 303 side of the signal processing circuit 103-1 side by side with the m column processing circuits 120 (120-1 to 120-m) included in the signal processing circuit 103-1 along the long side direction x.

The voltage generation circuit 320 is provided on the short side 304 side of the signal processing circuit 103-2 side by side with the m column processing circuits 120 (120-1 to 120-m) included in the signal processing circuit 103-2 along the long side direction x. The voltage generation circuit 320 generates a reference voltage and the like internal to the image reading chip 415 based on the voltage Vin2 input from the second voltage generation circuit 422, for example. Note that the voltage generation circuit 320 may be configured to include a regulator or the like, and generate various reference voltages.

The input/output portion 330 is provided on the long side 302 side of the two signal processing circuits 103-1 and 103-2, and is constituted by a plurality of electrodes and the operational amplifier 104 (unshown in FIG. 11) along the long side 302. That is, the input/output portion 330 includes electrodes for receiving signals and the like (such as clock signal CLK, resolution setting signal RES, and voltages Vin1 and Vin2) that are input from the reading control circuit 200 to the image reading chip 415, electrodes for transmitting and receiving the chip enable signals CE_in and CE_out, an electrode for outputting the image signal OS, and the like.

5. Configuration of Dummy Pixel and Dummy Column Processing Circuit

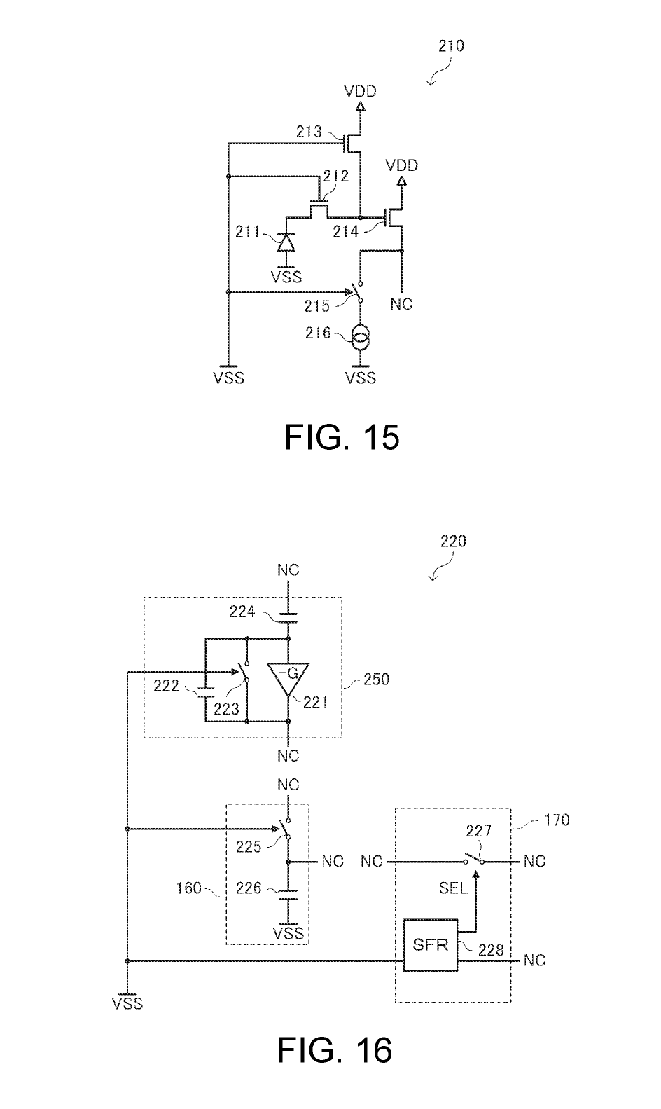

FIG. 15 is a diagram illustrating a circuit configuration of the dummy pixel circuit 210. The dummy pixel circuit 210 includes the photodetector 211, a transfer gate 212, NMOS transistors 213 and 214, a switch 215, and a constant current source 216. Note that “NC” shown in the diagram means non-connection.

The photodetector 211 receives light and converts it to an electric signal. In the present embodiment, the photodetector 211 is constituted by a photodiode whose anode is supplied with the ground potential VSS, and whose cathode is connected to one end of the transfer gate 212.

The ground potential VSS is applied to a control terminal of the transfer gate 212. Therefore, the transfer gate 212 is not turned on. Also, the other end of the transfer gate 212 is connected to a gate terminal of the NMOS transistor 214.

The NMOS transistor 213 has a drain terminal to which the power supply potential VDD is applied, and a source terminal connected to the gate terminal of the NMOS transistor 214. Also, the ground potential VSS is applied to the gate terminal. Therefore, the NMOS transistor 213 is not turned on.

The power supply potential VDD is applied to a drain terminal of the NMOS transistor 214, and a source terminal of the NMOS transistor 214 is connected to one end of the switch 215.

The other end of the switch 215 is connected to one end of the constant current source 216, and the ground potential VSS is applied to the other end of the constant current source 216. Also, the ground potential VSS is applied to a control terminal of the switch 215. The switch 215 is turned on when a signal at a high level is input to the control terminal. Therefore, the switch 215 is not turned on.

As described above, the dummy pixel circuit 210 in the present embodiment does not output a signal regardless of light input to the photodetector 211. Therefore, the dummy pixel circuit 210 is not involved in reading of an image.

In the present embodiment, the dummy pixel circuit 210 and the pixel circuit 110 (refer to FIG. 9) have a similar circuit configuration. Since disable signals are input to the dummy pixel circuit 210 (ground potential is applied), the dummy pixel circuit 210 is not involved in reading of the document P. As a result of the dummy pixel circuit 210 and the pixel circuit 110 having a similar configuration, variations in characteristics of the pixel circuits 110 at the end portions in the manufacturing process can further be reduced.

FIG. 16 is a diagram illustrating a circuit configuration of the dummy column processing circuit 220. The dummy column processing circuit 220 includes the dummy amplification circuit 250, the dummy holding circuit 260, and the dummy scanning circuit 270.

The dummy amplification circuit 250 includes an inverting amplifier 221, a capacitor 222, a switch 223, and a capacitor 224.

One end of the capacitor 224 is open (un-connected), and the other end thereof is connected to an input terminal of the inverting amplifier 221.

The inverting amplifier 221 is a grounded source amplifier constituted by a plurality of MOS transistors, for example. The capacitor 222 is a feedback capacitor of the inverting amplifier 221. The switch 223 is a feedback switch of the inverting amplifier 221. One end of the capacitor 222 and one end of the switch 223 are connected to the input terminal of the inverting amplifier 221, and the other end of the capacitor 222 and the other end of the switch 223 are connected to an output terminal of the inverting amplifier 221.

The ground potential VSS is applied to a control terminal of the switch 223. The switch 223 is turned on when a signal at a high level is input to a control terminal. Therefore, the switch 223 is not turned on.

That is, the dummy amplification circuit 250 does not include a path (interconnect) for receiving a signal and a path (interconnect) for outputting a signal. Therefore, the dummy amplification circuit 250 is not involved in reading of an image.

The dummy holding circuit 260 includes a switch 225 and a capacitor 226.

One end of the switch 225 is open (un-connected), and the other end thereof is connected to one end of the capacitor 226. The ground potential VSS is applied to the other end of the capacitor 226. The ground potential VSS is applied to a control terminal of the switch 225. The switch 225 is turned on when a signal at a high level is input to a control terminal. Therefore, the switch 225 is not turned on. Accordingly, charges are not accumulated in the capacitor 226. Therefore, the dummy holding circuit 260 is not involved in reading of an image.

The dummy scanning circuit 270 includes a switch 227 and a shift register (SFR) 228.

One end of the switch 227 is open (un-connected), and the other end thereof is open (un-connected) as well. Also, the selection signal SEL is input to a control terminal of the switch 227. The switch 227 is a column selection switch, and is turned on when the selection signal SEL is activated (high level in the present embodiment).

The ground potential VSS is applied to the shift register 228. Therefore, a selection signal SEL for controlling the switch 227 is output at a low level to the switch 227. That is, the switch 227 is not turned on. Therefore, the dummy scanning circuit 270 is not involved in reading of an image.

As described above, any of the dummy amplification circuit 250, the dummy holding circuit 260, and the dummy scanning circuit 270 included in the dummy column processing circuit 220 is not involved in reading of an image.

Here, the dummy column processing circuit 220 is configured similarly to the column processing circuit 120 shown in FIG. 9. As a result of the dummy column processing circuit 220 and the column processing circuit 120 having a similar configuration, variations in characteristics of the column processing circuit 120 at the end portions in the manufacturing process can further be reduced.

Also, in the present embodiment, all of the signals input to the dummy pixel circuit 210 and the dummy column processing circuit 220 are at the ground potential VSS. Furthermore, all of the signals input to the dummy amplification circuit 250, the dummy holding circuit 260, and the dummy scanning circuit 270 included in the dummy column processing circuit 220 are at the ground potential VSS.

In the present embodiment, the configuration in which there is no involvement in reading of an image is realized by turning off all the switches involved in the dummy pixel circuit 210 and the dummy column processing circuit 220. Furthermore, a configuration is adopted in which all of the signals that are input to the dummy pixel circuit 210, the dummy amplification circuit 250, the dummy holding circuit 260, and the dummy scanning circuit 270 are at the ground potential VSS. Accordingly, signals are not erroneously output when a malfunction occurs due to external noise or the like, for example. Therefore, influence of signals of the dummy pixel circuit 210 and the dummy column processing circuit 220 on an image can be reduced.

Note that, in the present embodiment, the switch 215 of the dummy pixel circuit 210, and the switches 223, 225, and 227 of the dummy column processing circuit 220 are each turned on when a signal at a high level is input. These switches may be a switch that is turned on when a signal at a low level is input, for example. In this case, the power supply potential VDD may be applied to the control terminals of the switches included in the dummy pixel circuit 210 and the dummy column processing circuit 220.

6. Action/Effect

As described above, the scanner unit (image reading device) 3 of the present embodiment is a divided optical reduction system scanner unit 3, and light from a reduced image of a portion of the document P is incident on each pixel circuit 110. That is, a reduced image is formed on the image reading chip 415. Therefore, the plurality of pixel circuits 110 need not be arranged up to an end portion of the image reading chip 415. Accordingly, the degree of freedom in the layout of circuits in the image reading chip 415 is increased.

Also, the scanner unit 3 of the present embodiment includes the image reading chip 415 in which the plurality of pixel circuits 110 that are involved in reading of the document P and the dummy pixel circuit 210 that is not involved in reading of the document P are included, and the plurality of pixel circuits 110 and the dummy pixel circuit 210 are provided side by side in a direction in which the long side 301 extends. Here, the dummy pixel circuit 210 is provided closer to the short side 303 relative to the plurality of pixel circuits 110. That is, the dummy pixel circuit 210 is provided at an end portion on the short side 303 side relative to the plurality of pixel circuits 110 provided side by side. As a result of arranging the dummy pixel circuit 210 that is not involved in reading of the document P at an end portion at which variations in characteristics caused by variations in manufacturing are large, variations in characteristics of the plurality of pixel circuits 110 that are involved in reading of an image can be reduced. Therefore, the accuracy in reading of the document P by the plurality of pixel circuits 110 can be improved, and the accuracy in reading of the document P by the scanner unit 3 is improved.

Also, the scanner unit 3 of the present embodiment includes the image reading chip 415 in which the plurality of pixel circuits 110 and the dummy pixel circuit 210 are formed in a region surrounded by the N-well 283. The P-well 282 region in which the plurality of pixel circuits 110 and the dummy pixel circuit 210 are formed are isolated from the surrounding region by the N-well 283. As a result of isolating the region in which the plurality of pixel circuits 110 and the dummy pixel circuit 210 are formed from another region, in the image reading chip 415, electrons that are not related to reading the document P flowing into the plurality of pixel circuits 110 can be reduced. Therefore, the document P can be accurately read using the plurality of pixel circuits 110, and the accuracy in reading of the document P can be improved in the scanner unit 3.

Also, the scanner unit 3 of the present embodiment includes the image reading chip 415 in which the plurality of amplification circuits 150 that are involved in reading of the document P and the dummy amplification circuit 250 that is not involved in reading of the document P are provided side by side along a direction in which the long side 301 extends. Here, the dummy amplification circuit 250 is provided closer to the short side 303 relative to the plurality of amplification circuits 150. That is, the dummy amplification circuit 250 is provided at an end portion on the short side 303 side relative to the plurality of amplification circuits 150 that are provided side by side. As a result of arranging the dummy amplification circuit 250 that is not involved in reading of the document P at an end portion at which variations in characteristics are large, variations in characteristics of the plurality of amplification circuits 150 that are involved in reading of the document P can be reduced. Accordingly, the plurality of amplification circuits 150 can each accurately amplify the pixel signal PIXO, and the accuracy in reading of an image can be improved in the scanner unit 3.

Also, the scanner unit 3 of the present embodiment includes the image reading chip 415 in which the plurality of scanning circuits 170 that are involved in reading of the document P and the dummy scanning circuit 270 that is not involved in reading of the document P are provided side by side along a direction in which the long side 301 extends. Here, the dummy scanning circuit 270 is provided closer to the short side 303 relative to the plurality of scanning circuits 170. That is, the dummy scanning circuit 270 is provided at an end portion on the short side 303 side relative to the plurality of scanning circuits 170 that are provided side by side. As a result of arranging the dummy scanning circuit 270 that is not involved in reading of the document P at an end portion at which variations in characteristics are large, variations in characteristics of the plurality of scanning circuits 170 that are involved in reading of the document P can be reduced. Accordingly, the plurality of scanning circuits 170 can each accurately amplify the pixel signal PIXO, and the accuracy in reading of an image can be improved in the image reading device.

7. Modifications

The scanner unit 3 in the present embodiment is configured such that a document P placed on the platen T is read, as shown in FIGS. 1 and 2, but may be a conveyance type scanner unit including an ADF (auto document feeder) and the like. Furthermore, the scanner unit 3 may be configured as a double-side reading type scanner that includes the image sensor modules 41 on both the surface and back surface of the document P, and reads the surface and back surface of the document P at the same time.

Also, in the dummy pixel circuit 210, the dummy amplification circuit 250, the dummy holding circuit 260, and the dummy scanning circuit 270 in the present embodiment, the control signals that are input to the respective circuits are disabled (control signals at the ground potential VSS, in the present embodiment), and the interconnects in the signal transfer paths between the circuits are not provided (NC: Non-Connection), but all the components included in each of the circuits may be left in an unconnected state.

For example, nodes of each of the photodetector 211, the transfer gate 212, the NMOS transistor 213, the NMOS transistor 214, the switch 215, and the constant current source 216, which are included in the dummy pixel circuit 210, excluding the node to which the ground potential VSS is applied may not be connected to another node. Also, nodes of each of the inverting amplifier 221, the capacitor 222, the switch 223, and the capacitor 224, which are included in the dummy amplification circuit 250, excluding the node to which the ground potential VSS is applied may not be connected to another node, for example. Also, nodes of each of the switch 225 and the capacitor 226, which are included in the dummy holding circuit 260, excluding the node to which the ground potential VSS is applied may not be connected to another node, for example. Also, nodes of each of the switch 227 and the shift register (SFR) 228, which are included in the dummy scanning circuit 270, excluding the node to which the ground potential VSS is applied may not be connected to another node, for example.

Furthermore, the dummy pixel circuit 210 and the pixel circuit 110, the dummy amplification circuit 250 and the amplification circuit 150, the dummy holding circuit 260 and the holding circuit 160, and the dummy scanning circuit 270 and the scanning circuit 170 may each have different sizes, shapes, or configurations. These modifications can also achieve similar effects to those of the above-described embodiment.

Although the embodiment and the modifications have been described above, the invention is not limited to these embodiment and the modifications, and can be carried out in various modes without departing from the gist of the invention. For example, the embodiment and the modifications can be combined as appropriate.

The invention includes substantially the same configurations (configurations with the same functions, methods, and results, or configurations with the same object and effect, for example) as the configurations described in the embodiment. The invention includes configurations in which an unessential part of the configurations described in the embodiment is replaced. The invention also includes configurations that achieve the same effect as that of the configurations described in the embodiment, or configurations that can achieve the same object as that of the configurations described in the embodiment. The invention also includes configurations obtained by adding a known technique to the configurations described in the embodiment.

This application claims priority from Japanese Patent Application No. 2017-056346 filed in the Japanese Patent Office on Mar. 22, 2017, the entire disclosure of which is hereby incorporated by reference in its entirely.

What is claimed is:

1. An image reading device comprising:
a first image reading chip that reads an image; and
an optical unit that forms a reduced image of the image on the first image reading chip,
wherein the first image reading chip includes:
a first pixel that includes a first photodetector that receives light of a reduced image of the image and performs photoelectric conversion, and generates a first pixel signal by amplifying a signal generated by the photoelectric conversion;
a second pixel that includes a second photodetector that receives light of a reduced image of the image and performs photoelectric conversion, and generates a second pixel signal by amplifying a signal generated by the photoelectric conversion;
a first readout circuit that is electrically connected to the first pixel and outputs a first readout signal based on the first pixel signal;
a second readout circuit that is electrically connected to the second pixel and outputs a second readout signal based on the second pixel signal; and
a pseudo pixel that is not involved in reading of the image,
wherein the first image reading chip has a shape that includes a first side and a second side that is shorter than the first side,
the first pixel, the second pixel, and the pseudo pixel are arranged side by side in a direction in which the first side extends,
a distance between the pseudo pixel and the second side is shorter than a distance between the first pixel and the second side, and
the distance between the pseudo pixel and the second side is shorter than a distance between the second pixel and the second side.

2. The image reading device according to claim 1, wherein the first pixel, the second pixel, and the pseudo pixel are arranged in a region that is surrounded by the same well.

3. The image reading device according to claim 2,
wherein the first image reading chip includes:
a first amplification circuit that is included in the first readout circuit, and amplifies and outputs the first pixel signal;
a second amplification circuit that is included in the second readout circuit, and amplifies and outputs the second pixel signal; and
a pseudo amplification circuit that is not involved in reading the image,
wherein the first amplification circuit, the second amplification circuit, and the pseudo amplification circuit are arranged side by side in a direction in which the first side extends,
a distance between the pseudo amplification circuit and the second side is shorter than a distance between the first amplification circuit and the second side, and
the distance between the pseudo amplification circuit and the second side is shorter than a distance between the second amplification circuit and the second side.

4. The image reading device according to claim 2,
wherein the first image reading chip includes:
a first scanning circuit that is included in the first readout circuit, and controls a readout timing of the amplified first pixel signal;
a second scanning circuit that is included in the second readout circuit, and controls a readout timing of the amplified second pixel signal; and
a pseudo scanning circuit that is not involved in reading of the image,
wherein the first scanning circuit, the second scanning circuit, and the pseudo scanning circuit are arranged side by side in a direction in which the first side extends,
a distance between the pseudo scanning circuit and the second side is shorter than a distance between the first scanning circuit and the second side, and
the distance between the pseudo scanning circuit and the second side is shorter than a distance between the second scanning circuit and the second side.

5. The image reading device according to claim 1, further comprising a second image reading chip,
wherein the image includes a first partial image and a second partial image,
the optical unit
forms a reduced image of the first partial image on the first image reading chip, and
forms a reduced image of the second partial image on the second image reading chip.

6. The image reading device according to claim 4,
wherein the first image reading chip includes:
a drive control circuit that generates a scan signal for controlling operations of the first scanning circuit and the second scanning circuit,
the distance between the drive control circuit and the second side is shorter than the pseudo scanning circuit and the second side.

7. A semiconductor device, having a shape including a first side and a second side that is shorter than the first side, comprising:
a first pixel that includes a first photodetector that receives light of a reduced image of a portion of an image and performs photoelectric conversion, and generates a first pixel signal by amplifying a signal generated by the photoelectric conversion;
a second pixel that includes a second photodetector that receives light of a reduced image of a portion of the image and performs photoelectric conversion, and generates a second pixel signal by amplifying a signal generated by the photoelectric conversion;
a first readout circuit that is electrically connected to the first pixel and outputs a first readout signal based on the first pixel signal;
a second readout circuit that is electrically connected to the second pixel and outputs a second readout signal based on the second pixel signal; and
a pseudo pixel that is not involved in reading the image,
wherein the first pixel, the second pixel, and the pseudo pixel are arranged side by side in a direction in which the first side extends,
a distance between the pseudo pixel and the second side is shorter than a distance between the first pixel and the second side, and
the distance between the pseudo pixel and the second side is shorter than a distance between the second pixel and the second side.
